(19) United States
(12) Patent Application Publication
(10) Pub. No.: US 2017/0155203 A1
(43) Pub. Date: Jun. 1, 2017

(54) TERMINAL-EQUIPPED PRINTED CIRCUIT BOARD

(71) Applicant: Sumitomo Wiring Systems, Ltd, Yokkaichi, Mie (JP)

(72) Inventor: Hideki Goto, Yokkaichi, Mie (JP)

(73) Assignee: Sumitomo Wiring Systems, Ltd, Yokkaichi, Mie (JP)

(21) Appl. No.: 15/321,022

(22) PCT Filed: Jun. 12, 2015
(86) PCT No.: PCT/JP2015/067030

§ 371 Date: Dec. 21, 2016

(30) Foreign Application Priority Data
Jun. 27, 2014 (JP) 2014-132170
Nov. 21, 2014 (JP) 2014-237057

(51) Int. Cl. H01R 12/58; H05K 1/11

(52) U.S. Cl. CPC H01R 12/585; H05K 1/11

(57) ABSTRACT

The present invention provides a terminal-equipped printed circuit board having a novel structure in which a circuit board terminal is stably positioned on and fixed to a printed circuit board, and conduction stability between the circuit board terminal and a conduction portion provided in a through-hole of the printed circuit board can be ensured without needing a soldering step. The printed circuit board includes press-in holes and through-holes that have conduction portions, and the circuit board terminal includes press-in protrusions and press-fit lead portions that have press-fit portions. The circuit board terminal and the conduction portions are brought into conduction by the press-fit lead portions being inserted into the through-holes and the press-fit portions being press-fitted against the conduction portions of the through-holes. The circuit board terminal is positioned on and fixed to the printed circuit board by the press-in protrusions being pressed into the press-in holes.

### CROSS-REFERENCE TO RELATED APPLICATIONS

This application is the U.S. national stage of PCT/JP2015/067030 filed Jun. 12, 2015, which claims priority of Japanese Patent Application No. JP2014-132170 filed Jun. 27, 2014 and Japanese Patent Application No. JP2014-237057 filed Nov. 21, 2014.

### FIELD OF THE INVENTION

The present invention relates to a terminal-equipped printed circuit board in which a circuit board terminal is provided upright on the upper surface of a printed circuit board.

### BACKGROUND

Conventionally, terminal-equipped printed circuit boards have been widely used as internal circuits in automobile electrical junction boxes, for example. With such a terminal-equipped printed circuit board, lead portions provided at the base portions of circuit board terminals are inserted into through-holes in a printed circuit board and connected by soldering to conduction portions provided in the through-holes, whereas tab-shaped or tuning fork-shaped connection portions provided at the tip portions of the circuit board terminals protrude upward from the printed circuit board, and can be connected to electrical parts such as fuses or relays.

Incidentally, when the circuit board terminals are connected by soldering to the conduction portions provided in the through-holes of the printed circuit board, it is important to hold the circuit board terminals such that the force of insertion and removal of the electrical parts does not directly act on the soldered portions of the circuit board terminals during use. In view of this, conventionally, as disclosed in JP 2003-217437A for example, the circuit board terminals have been held in a state of being press-fitted into and held in a synthetic resin pedestal, and this pedestal has been held between the printed circuit board and the case.

However, if the circuit board terminals are held using such a synthetic resin pedestal, there has been a problem in that when soldering is performed, due to the difference between the linear expansion coefficients of the printed circuit board and the pedestal, the circuit board terminals and the printed circuit board become relatively displaced, and solder cracks are readily formed. Moreover, the pedestal is a separate part that is needed, and the pedestal also needs to be held by a jig during soldering, and therefore it is not possible to avoid an increase in the number of parts and an increase in the complexity of the manufacturing process, thus leading to the problem of an increase in cost as well.

In view of this, in JP 2011-228214A and the like, the applicant of this application has made a proposal in which press-in protrusions are integrally provided on the circuit board terminals, and these press-in protrusions are pressed into press-in holes provided in the printed circuit board, thus holding the circuit board terminals in a self-standing state on the printed circuit board. Accordingly, the circuit board terminals can be soldered without using a pedestal, and it is possible to eliminate problems such as the formation of solder cracks during soldering and an increase in the number of parts.

However, a complicated soldering step is necessary in the first place because the lead portions of the circuit board terminals are connected by soldering to the conduction portions provided in the through-holes of the printed circuit board. Furthermore, if excessive force for insertion or removal of an electrical part acts on the soldered portions via the circuit board terminals, there is a risk of cracks, ruptures, and the like forming in the soldered portions, and a risk of problems with conduction stability, and there have been cases where it is necessary to take a countermeasure such as holding the circuit board terminals on the case side.

The present invention was achieved in light of the above-described circumstances, and a problem to be solved is providing a terminal-equipped printed circuit board having a novel structure in which a circuit board terminal is stably positioned on and fixed to a printed circuit board, and conduction stability between the circuit board terminal and a conduction portion provided in a through-hole of the printed circuit board can be ensured without needing a soldering step.

### SUMMARY OF INVENTION

A first aspect of the present invention is a terminal-equipped printed circuit board in which a circuit board terminal is provided upright on an upper surface of a printed circuit board, wherein the printed circuit board includes a press-in hole and a through-hole that has a conduction portion, the circuit board terminal includes a press-in protrusion and a press-fit lead portion that has a press-fit portion, the circuit board terminal and the conduction portion are brought into conduction by the press-fit lead portion being inserted into the through-hole and the press-fit portion being press-fitted against the conduction portion of the through-hole, and the circuit board terminal is positioned on and fixed to the printed circuit board by the press-in protrusion being pressed into the press-in hole.

According to this aspect, the circuit board terminal is positioned on and fixed to the printed circuit board by the press-in protrusion of the circuit board terminal being pressed into the press-in hole of the printed circuit board. Accordingly, the circuit board terminal can be held in a self-standing state on the printed circuit board without needing another member such as a pedestal. Moreover, the connection of the press-fit lead portion of the circuit board terminal to the conduction portion provided in the through-hole of the printed circuit board can be achieved by press-fitting the press-fit portion of the press-fit lead portion against the conduction portion provided in the through-hole, rather than by performing soldering. Accordingly, even if excessive insertion or removal force is applied to the circuit board terminal, conventional problems such as the formation of cracks and the like in the soldered portion do not occur, and, due to the press-fitting force of the press-fit lead portion, the press-fit portion can be stably held against the conduction portion, and stable conductivity can be ensured.

A second aspect of the present invention is the first aspect wherein the press-fit lead portion has a locking protrusion portion located on a tip side relative to the press-fit portion, the press-fit lead portion undergoes elastic deformation due to the locking protrusion portion being inserted into the through-hole, and, when the locking protrusion portion has passed through the through-hole, the press-fit lead portion undergoes elastic restoration and the locking protrusion portion becomes locked to a lower surface of the printed circuit board.

According to this aspect, the locking protrusion portion is provided on the press-fit lead portion of the circuit board terminal, and the locking protrusion portion can be stably held at a position of being locked and fixed to the lower surface of the printed circuit board by the elastic restoration force of the press-fit lead portion, that is to say the press-fitting force of the press-fit lead portion. Accordingly, when force for removal of an electrical part is applied to the circuit board terminal, the circuit board terminal can be stably held on the printed circuit board, and it is possible to ensure more stable positioning and fixture of the circuit board terminal on the printed circuit board.

A third aspect of the present invention is the first or second aspect wherein the press-fit lead portion has an abutting protrusion portion located on a base side relative to the press-fit portion, and in a state in which the circuit board terminal is mounted to the printed circuit board, the abutting protrusion portion abuts against the upper surface of the printed circuit board.

According to this aspect, the abutting protrusion portion abuts against the upper surface of the printed circuit board. Accordingly, even if excessive insertion force is applied to the circuit board terminal, the excessive insertion force can be distributed, thus making it possible for the circuit board terminal to be able to be stably held in a self-standing state on the printed circuit board.

A fourth aspect of the present invention is any one of the first to third aspects wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

According to this aspect, the first and second press-fit portions protrude in a circular arc shape toward respective sides in the plate thickness direction of the flat plate-shaped connection portion, and therefore press-fitting force toward both sides in the plate thickness direction can be applied to press-fit the press-fit portions against the conduction portion in the through-hole. Accordingly, it is possible to ensure both positioning stability and conduction stability for the circuit board terminal. Moreover, since the press-fit portions protrude in a circular arc shape, when the press-fit lead portion is inserted into the through-hole, the lower sides of the circular arc-shaped press-fit portions, which gradually increase in protruding dimension toward the two sides in the plate thickness direction, serve as guides so as to enable the press-fit lead portion to be smoothly inserted into the through-hole. Additionally, the surfaces of the circuit board terminal on the plate thickness direction sides, which are the plated surfaces, can be used as the press-fit portions, thus making it possible to advantageously ensure conduction stability for the circuit board terminal.

A fifth aspect of the present invention is the fourth aspect wherein the circuit board terminal has a first press-fit lead portion and a second press-fit lead portion that are provided at positions with a gap therebetween in a plate width direction of the connection portion, the first press-fit lead portion has the first press-fit portion in an intermediate portion with respect to a length direction, and the second press-fit lead portion has the second press-fit portion in an intermediate portion with respect to the length direction.

According to this aspect, the first press-fit lead portion and the second press-fit lead portion are separated from each other in the plate width direction of the connection portion, and have the first press-fit portion and the second press-fit portion that protrude to respective sides in the plate thickness direction, and therefore circuit board terminals having the flat plate-shaped connection portions can be held on the printed circuit board while stably positioning the connection portions at symmetric positions across a gap.

A sixth aspect of the present invention is the first or second aspect wherein a tip side of the circuit board terminal, which protrudes above the upper surface of the printed circuit board and is connected to a base side on which the press-fit lead portion and the press-in protrusion are provided, is a flat plate-shaped connection portion, and the circuit board terminal has a first press-fit lead portion and a second press-fit lead portion that are provided at positions with a gap therebetween in a plate width direction of the connection portion, and the first press-fit lead portion and the second press-fit lead portion are formed with a curved shape so as to protrude outward toward respective sides in the plate width direction of the connection portion, and protruding end surfaces of the press-fit lead portions are the press-fit portions.

According to this aspect, the first and second press-fit portions of the first press-fit lead portion and the second press-fit lead portion, which are provided at positions with a gap in the plate width direction of the flat plate-shaped connection portion, protrude in a circular arc shape toward respective sides in the plate width direction, and therefore press-fitting force toward both sides in the plate width direction can be applied to press-fit the press-fit portions against the conduction portion in the through-hole. Accordingly, it is possible to ensure both positioning stability and conduction stability for the circuit board terminal.

A seventh aspect of the present invention is any one of the first to sixth aspects wherein the circuit board terminal has an abutting surface that abuts against the upper surface of the printed circuit board, and a cut portion is formed so as to extend upward from the abutting surface in a direction away from the printed circuit board such that a base portion of the press-fit lead portion is located higher than the abutting surface is.

According to this aspect, due to the cut portion that extends upward from the abutting surface of the circuit board terminal that abuts against the printed circuit board, the base portion of the press-fit lead portion is located farther away from the printed circuit board than the abutting surface is, and therefore the arm length of the press-fit lead portion during elastic deformation can be extended without changing the length of the circuit board terminal itself, thus making it possible to reduce the amount of insertion force needed for insertion of the circuit board terminal into the through-hole.

An eighth aspect of the present invention is any one of the first to seventh aspects wherein a tip side of the circuit board terminal, which protrudes above the upper surface of the printed circuit board and is connected to a base side on which the press-fit lead portion and the press-in protrusion are provided, is a flat plate-shaped connection portion, and the press-fit lead portion and the press-in protrusion are provided at different positions from each other in a plate thickness direction of the connection portion.

According to this aspect, the press-fit lead portion and the press-in protrusion, which are provided at different positions from each other in the plate thickness direction of the connection portion, are respectively inserted into the through-hole and the press-in hole of the printed circuit board, thus advantageously suppressing inclination and rotation of the circuit board terminal on the printed circuit board, and making it possible to more stably maintain the upright state and conductivity of the circuit board terminal.

A ninth aspect of the present invention is the eighth aspect wherein the circuit board terminal that includes the press-fit lead portion, the press-in protrusion, and the connection portion is formed in an integrated manner by performing punching on a metal flat plate, the press-in protrusion is located in a central portion with respect to a plate width direction of the connection portion, and the press-fit lead portion, which is joined to the press-in protrusion via a junction portion that protrudes to one side from the press-in protrusion, is provided at a position that is separated from the press-fit lead portion in the plate thickness direction of the connection portion by bending the junction portion.

According to this aspect, with use of the simple processing of press punching a metal flat plate and bending the junction portion that joins the press-fit lead portion and the press-in protrusion, it is possible to provide the press-fit lead portion and the press-in protrusion at a different positions from each other in the plate thickness direction of the connection portion. Moreover, the press-in protrusion can be provided at the same position as the connection portion in the plate thickness direction of the connection portion, and therefore the press-in protrusion can be held more stably against external force applied when an external terminal is connected to the connection portion.

A tenth aspect of the present invention is the eighth or ninth aspect wherein a slit that extends in a length direction of the press-fit lead portion is provided so as to penetrate a central portion of the press-fit lead portion, central portions, with respect to the length direction, of portions of the press-fit lead portion on respective sides of the slit respectively protrude toward one side and another side in a thickness direction of the press-fit lead portion and thus constitute a pair of elastic press-fit pieces, and the press-fit portion is constituted by outward surfaces of the pair of elastic press-fit pieces.

According to this aspect, the two sides of the slit provided in the central portion of the press-fit lead portion protrude in mutually opposite directions, thus constituting the press-fit lead portion. Accordingly, the press-fit lead portion can be pressed into the through-hole with a small amount of press-in force, and an advantageous area of press-fitting of the press-fit portion against the through-hole can be ensured. Even with the press-fit lead portion having such an action pin shape, the positions of the press-fit lead portion and the press-in protrusion are different from each other in the plate thickness direction of the connection portion, thus making it possible to advantageously prevent rolling of the circuit board terminal.

According to the present invention, the circuit board terminal can be positioned on and fixed to the printed circuit board by the press-in protrusion being pressed into the press-in hole of the printed circuit board, thus not needing another member such as a pedestal. Moreover, the connection of the press-fit lead portion of the circuit board terminal to the conduction portion provided in the through-hole of the printed circuit board can be achieved by press-fitting the press-fit portion of the press-fit lead portion against the conduction portion provided in the through-hole, rather than by performing soldering, and therefore even if excessive insertion or removal force is applied to the circuit board terminal, conventional problems such as the formation of cracks and the like in the soldered portion do not occur, and the press-fit portion can be stably held against the conduction portion, and stable conductivity can be ensured.

### BRIEF DESCRIPTION OF DRAWINGS

FIG. 1 is a perspective view of a terminal-equipped printed circuit board according to a first embodiment of the present invention.

FIG. 2 is an enlarged cross-sectional view taken along II-II in FIG. 1.

FIG. 3 is a bottom view of the terminal-equipped printed circuit board shown in FIG. 1.

FIG. 4 is a perspective view of another aspect of the terminal-equipped printed circuit board shown in FIG. 1.

FIG. 5 is a perspective view of a terminal-equipped printed circuit board according to a second embodiment of the present invention.

FIG. 6 is an enlarged cross-sectional view taken along VI-VI in FIG. 5.

FIG. 7(a) is a development diagram for describing a method for manufacturing a circuit board terminal shown in FIG. 5 showing a state after press punching, and FIG. 7 (b) shows a state after folding.

FIG. 8 is a perspective view of a terminal-equipped printed circuit board according to a third embodiment of the present invention.

FIG. 9 is a side view of the terminal-equipped printed circuit board shown in FIG. 8.

FIG. 10 is a perspective view of a terminal-equipped printed circuit board according to a fourth embodiment of the present invention.

FIG. 11 is a front view of the terminal-equipped printed circuit board shown in FIG. 10.

FIG. 12 is a perspective view of another aspect of the terminal-equipped printed circuit board shown in FIG. 10.

FIG. 13 is a front view of the terminal-equipped printed circuit board shown in FIG. 12.

FIG. 14 is a perspective view of a terminal-equipped printed circuit board according to a fifth embodiment of the present invention.

FIG. 15 is a perspective view of a circuit board terminal shown in FIG. 14.

FIG. 16(a) is a development diagram for describing a method for manufacturing the circuit board terminal shown in FIG. 15 showing a state after press punching, and FIG. 16(b) shows a state after bending.

### DETAILED DESCRIPTION OF THE PREFERRED EMBODIMENTS

Hereinafter, embodiments of the present invention will be described with reference to the drawings.

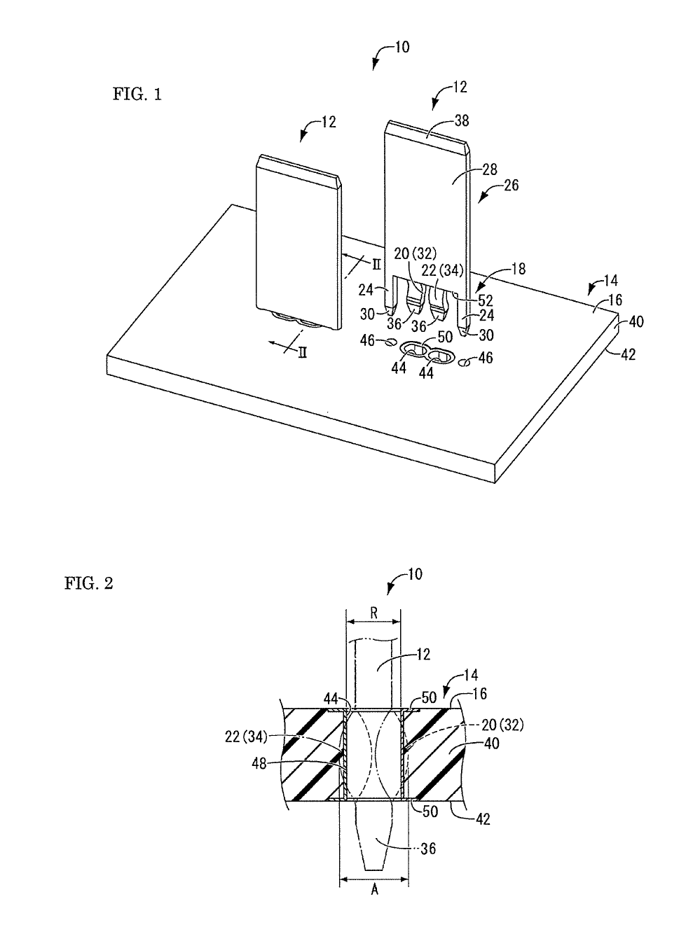

FIGS. 1 to 3 show a terminal-equipped printed circuit board 10 according to a first embodiment of the present invention. The terminal-equipped printed circuit board 10 has a structure in which circuit board terminals 12 are provided upright on an upper surface 16 of a printed circuit board 14. Note that in the following description, the length direction and the up-down direction refer to the up-down direction in FIG. 1, and the plate width direction refers to the left-right direction in FIG. 1. Also, the plate thickness direction refers to the left-right direction in FIG. 2. Furthermore, in order to facilitate understanding in FIG. 2, the state of a circuit board terminal 12 before elastic deformation is indicated by virtual lines.

Each circuit board terminal 12 is shaped as a flat plate, and is formed by performing press punching on a metal plate such as a copper plate whose surface has been plated with tin or the like. First and second press-fit lead portions 20 and 22 and a pair of press-in protrusions 24, 24 are formed on a base side 18, with respect to the length direction, of the circuit board terminal 12, and a flat plate-shaped connection portion 28 that is continuous with the base side 18 is formed on a tip side 26, with respect to the length direction, of the circuit board terminal 12.

The press-in protrusions 24 are provided on the two side portions, with respect to the plate width direction of the connection portion 28, of the base side 18 of the circuit board terminal 12, and protrude outward in the length direction (downward in FIG. 1) in the shape of a narrow flat plate. Similarly to circuit board terminals that have been used conventionally, a tapered tip portion 30 is formed at the tip edge portion of each of the press-in protrusions 24. Also, the first and second press-fit lead portions 20 and 22 are provided in the central portion, with respect to the plate width direction of the connection portion 28, of the base side 18, are separated from each other in the plate width direction of the connection portion 28, and likewise protrude outward in the length direction in the shape of a wide flat plate. A first press-fit portion 32 is provided in an intermediate portion, with respect to the length direction, of the first press-fit lead portion 20 and protrudes rearward, which is toward one side in the plate thickness direction of the connection portion 28, with a circular arc shape, and a second press-fit portion 34 is provided in an intermediate portion, with respect to the length direction, of the second press-fit lead portion 22 and protrudes forward, which is toward the other side in the plate thickness direction of the connection portion 28, with a circular arc shape. Note that similarly to the press-in protrusions 24, a tapered tip portion 36 is formed at the tip edge portion of each of the first and second press-fit lead portions 20 and 22 as well.

Also, the connection portion 28 is approximately shaped as a vertically elongated rectangular flat plate, and, similarly to the first and second press-fit lead portions 20 and 22 and the press-in protrusions 24, a tapered tip portion 38 is formed at the tip edge portion of the connection portion 28 as well. The connection portion 28 is arranged so as to protrude above the upper surface 16 of the printed circuit board 14, and is connected to a partner terminal (not shown) by being fitted thereto.

The printed circuit board 14 is obtained by providing printed wiring (not shown) on the upper surface 16 and a lower surface 42 of an insulated substrate 40 that is approximately shaped as a rectangular flat plate and is formed from a known insulating material such as glass epoxy resin. Also, a pair of through-holes 44, 44 and a pair of press-in holes 46, 46, which are for insertion of the first and second press-fit lead portions 20 and 22 and the press-in protrusions 24 of the circuit board terminal 12, are formed in the printed circuit board 14.

The through-holes 44 have an approximately elliptical cross-sectional shape, and a diameter dimension R thereof in the minor axis direction is smaller than a dimension A of the separation between the protruding end surfaces, with respect to the plate thickness direction of the connection portion 28, of the first and second press-fit portions 32 and 34 (R is lesser than A). Also, a plating layer 48 that serves as a conduction portion is formed on the entirety of the inner circumferential surface of each of the through-holes 44, and these plating layers 48 are connected to the printed wiring (not shown). Land portions 50 are provided in the periphery of the openings of the through-holes 44 on the upper surface 16 side and the lower surface 42 side of the printed circuit board 14. Also, the press-in holes 46 have an approximately circular cross-sectional shape, and a diameter dimension r thereof is smaller than a diagonal dimension a of a rectangular cross-section of the press-in protrusions 24 of the circuit board terminal 12 (R is lesser than A).

The first and second press-fit lead portions 20 and 22 and the pair of press-in protrusions 24, 24 of the circuit board terminal 12 are inserted into the pair of through-holes 44, 44 and the pair of press-in holes 46, 46 of the printed circuit board 14 having the above-described structures, from the upper surface 16 side of the printed circuit board 14 toward the lower surface 42 side. The amount of insertion of the base side 18 of the circuit board terminal 12 into the through-holes 44 and the press-in holes 46 is defined by an abutting surface 52 abutting against the upper surface 16 of the printed circuit board 14, and the circuit board terminal 12 is positioned on and fixed to the printed circuit board 14 by the press-in protrusions 24 being pressed into the press-in holes 46. Also, as the first and second press-fit lead portions 20 and 22 are inserted into the through-holes 44, they undergo elastic deformation toward the interior of the through-holes 44 with their base ends serving as the center of rotation. The first and second press-fit portions 32 and 34 provided on the first and second press-fit lead portions 20 and 22 are then held in a state of being press-fitted against the plating layers 48 provided on the inner circumferential surfaces of the through-holes 44. As a result, the circuit board terminal 12 is in conduction with the printed wiring (not shown) formed on the printed circuit board 14 via the plating layers 48.

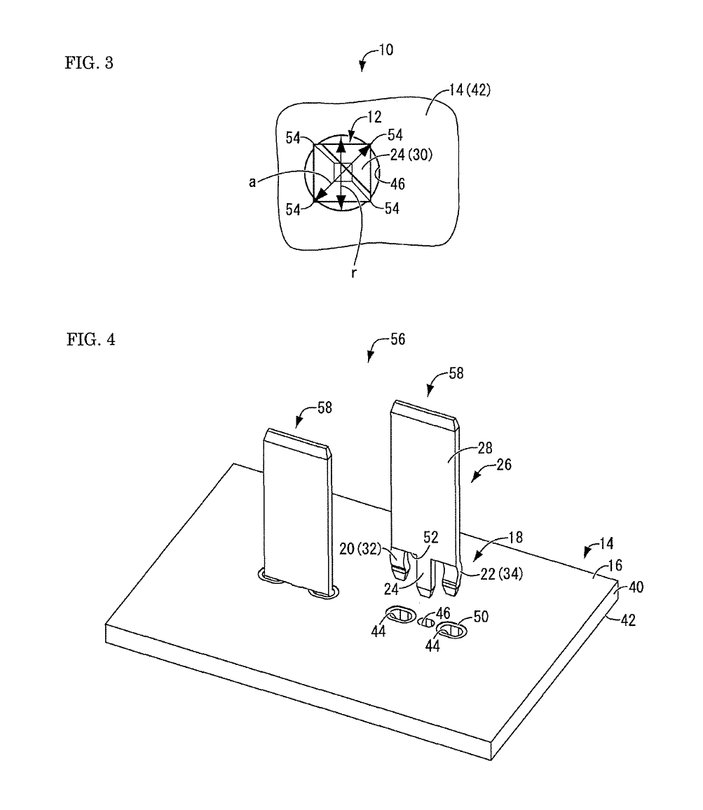

According to the terminal-equipped printed circuit board 10 having such a structure, the diameter dimension r of the press-in holes 46 is smaller than the diagonal dimension a of the rectangular cross-section of the press-in protrusions 24, and therefore the press-in protrusions 24 are pressed into the press-in holes 46 in a state in which four corner portions 54 of the press-in protrusions 24 are press-fitted against the inner circumferential surfaces of the press-in holes 46 (see FIG. 3). Accordingly, there is no need for other members such as a pedestal, and the circuit board terminal 12 can be held in a self-standing and non-rotatable state on the printed circuit board 14.

Also, the first and second press-fit portions 32 and 34 are provided so as to protrude in a circular arc shape on the two sides, with respect to the plate thickness direction, of the flat plate-shaped connection portion 28, and therefore press-fitting force toward both sides in the plate thickness direction can be applied to press-fit the first and second press-fit portions 32 and 34 against the plating layers 48 formed on the inner circumferential surfaces of the through-holes 44. Accordingly, the circuit board terminals 12 can be held on the printed circuit board 14 while ensuring conduction stability and more stably positioning the connection portions 28 at symmetric positions across a gap. Additionally, the first and second press-fit portions 32 and 34 are formed so as to protrude in the shape of a circular arc, and therefore when the first and second press-fit lead portions 20 and 22 are inserted into the through-holes 44, the lower sides of the circular arc-shaped first and second press-fit portions 32 and 34, which gradually increase in protruding dimension toward the two sides in the plate thickness direction, serve as guides so as to enable the first and second press-fit lead portions 20 and 22 to be smoothly inserted into the through-holes 44. Moreover, the connection between the circuit board terminals 12 and the printed circuit board 14 is achieved not by soldering, but rather by the first and second press-fit portions 32 and 34 provided on the first and second press-fit lead portions 20 and 22 of the circuit board terminal 12 being press-fitted against the plating layers 48 formed on the inner circumferential surfaces of the through-holes 44. Accordingly, even if excessive insertion or removal force is applied to the circuit board terminal 12, conventional problems such as the formation of cracks and the like in the soldered portions do not occur, and, due to the press-fitting force of the first and second press-fit lead portions 20 and 22, the first and second press-fit portions 32 and 34 can be stably held against the plating layers 48, and stable conductivity can be ensured.

Next, a terminal-equipped printed circuit board 56 according to another aspect of the present embodiment will be described in detail with reference to FIG. 4. Members and portions having a structure similar to those in the above embodiment will be denoted in this figure by the same reference signs as in the above embodiment, thereby omitting detailed descriptions for them. The present embodiment is different from the above embodiment in that, the first and second press-fit lead portions 20 and 22 are provided on the two side portions, with respect to the plate width direction of the connection portion 28, of the base side 18 of the circuit board terminal 58, and one press-in protrusion 24 is provided in the central portion, with respect to the plate width direction of the connection portion 28, of the base side 18.

Even if, as in the present embodiment, the arrangement locations of the first and second press-fit lead portions 20 and 22 and the press-in protrusion 24 are different from the first embodiment, effects similar to those of the first embodiment are obtained. Specifically, the press-in protrusion 24 is pressed into the press-in hole 46, and therefore the circuit board terminal 58 is positioned on and fixed to the printed circuit board 14. Moreover, the first and second press-fit lead portions 20 and 22 are press-fitted against the plating layers 48 provided on the inner circumferential surfaces of the through-holes 44, and therefore the circuit board terminals 58 can be held on the printed circuit board 14 while ensuring conduction stability and more stably positioning the connection portions 28 at symmetric positions across a gap.

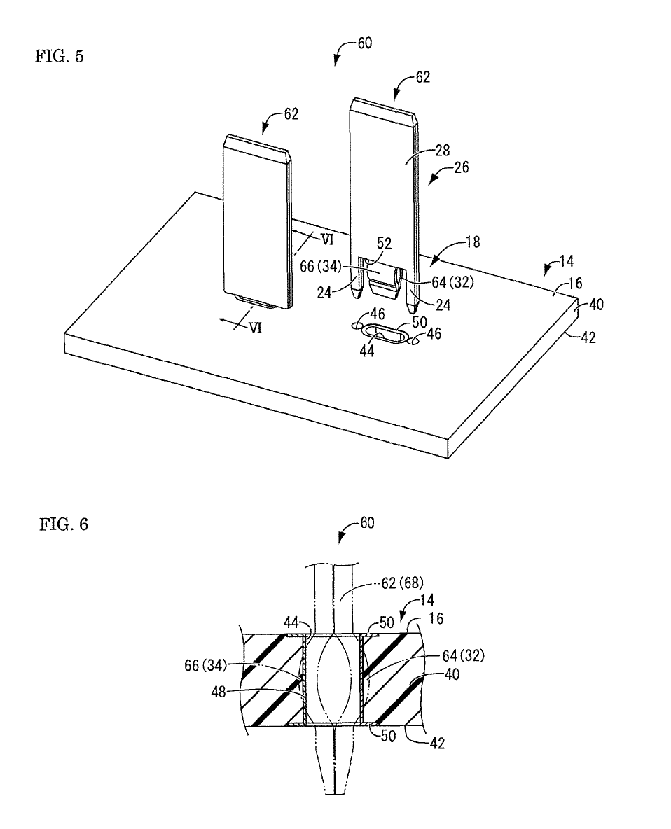

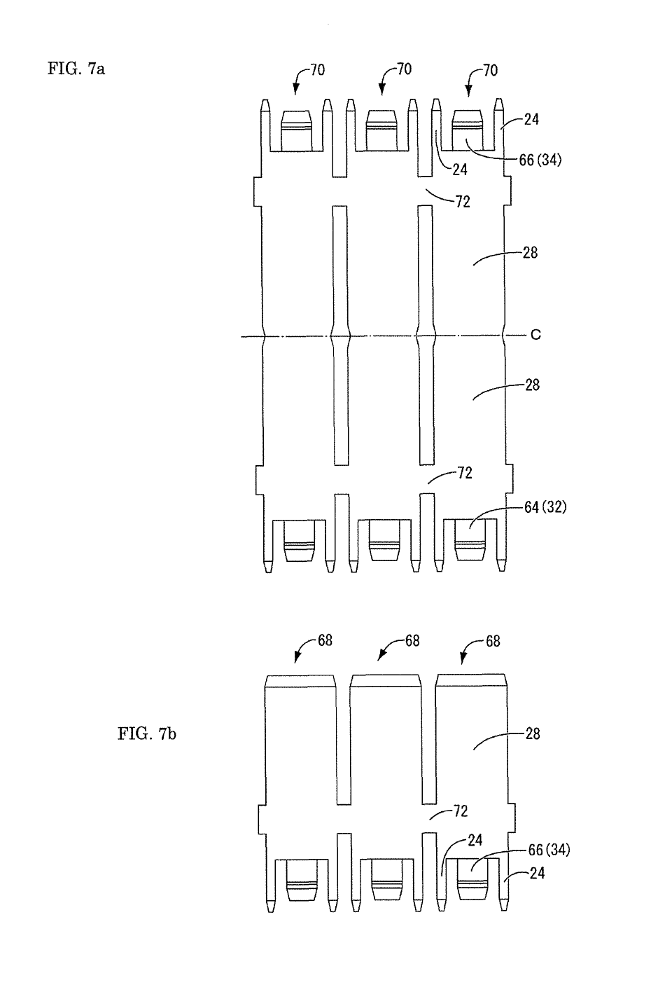

Next, a terminal-equipped printed circuit board 60 according to a second embodiment of the present invention will be described in detail with reference to FIGS. 5 to 7(b). Members and portions having a structure similar to those in the above embodiment will be denoted in these figures by the same reference signs as in the above embodiment, thereby omitting detailed descriptions for them. The present embodiment is different from the first embodiment in that a first press-fit lead portion 64 and a second press-fit lead portion 66 of a circuit board terminal 62 are formed so as to overlap each other in a side view, and are formed by a double-walled member 68. Specifically, when forming the circuit board terminal 62 of the present embodiment, as shown in FIG. 7(a) for example, a flat plate member 70 is formed by performing press punching on a metal plate such as a copper plate whose surface has been plated with tin or the like. The flat plate member 70 is constituted to include a pair of connection portions 28, 28 that are punched out in a line symmetrical manner across a center line C, the first press-fit lead portion 64 and the second press-fit lead portion 66, and a pair of press-in protrusions 24, 24. Next, as shown in FIG. 7(b), this flat plate member 70 is folded onto itself in the plate thickness direction at the center line C, thus forming a double-walled member 68. Lastly, junction portions 72 are cut away, thus completing the circuit board terminal 62 constituted by the double-walled member 68.

In the present embodiment as well, effects similar to those of the first embodiment are obtained. Specifically, the press-in protrusions 24 and the press-in holes 46 have exactly the same structure as in the first embodiment, and the first press-fit lead portion 64 and the second press-fit lead portion 66 are also no different in that they are press-fitted against the plating layer 48 provided on the inner circumferential surface of the through-hole 44, and therefore the circuit board terminals 62 can be held on the printed circuit board 14 while ensuring conduction stability and more stably positioning the connection portions 28 at symmetric positions across a gap. Moreover, in the present embodiment, the circuit board terminal 62 is constituted by the double-walled member 68 that is folded onto itself in the plate thickness direction at the center line C, and therefore a structure in which the first press-fit lead portion 64 and the second press-fit lead portion 66 overlap each other in a side view can be easily formed.

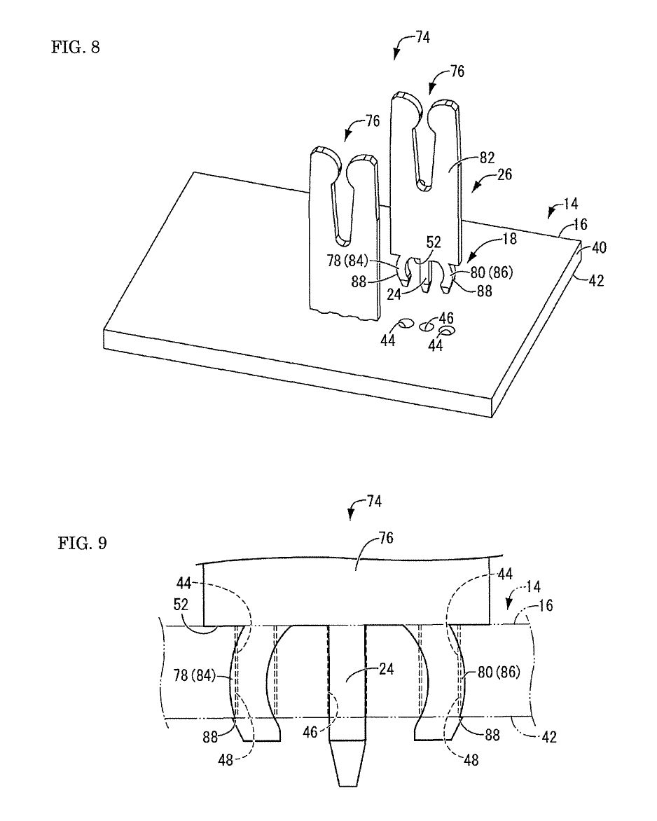

Next, a terminal-equipped printed circuit board 74 according to a third embodiment of the present invention will be described in detail with reference to FIGS. 8 and 9. Members and portions having a structure similar to those in the above embodiments will be denoted in these figures by the same reference signs as in the above embodiments, thereby omitting detailed descriptions for them. This terminal-equipped printed circuit board 74 is different from the other aspect of the first embodiment in that a first press-fit lead portion 78 and a second press-fit lead portion 80 of a circuit board terminal 76 are deformed in a curved shape so as to protrude outward toward respective sides in the plate width direction of the connection portion 82 that has a tuning fork shape.

In the present embodiment as well, effects similar to those of the other aspect of the first embodiment are obtained. Specifically, the press-in protrusions 24 and the press-in holes 46 have exactly the same structure as in the other aspect of the first embodiment, and the first and second press-fit lead portions 78 and 80 merely have different curving directions and are no different in that they are press-fitted against the plating layers 48 provided on the inner circumferential surfaces of the through-holes 44, and therefore the circuit board terminals 76 can be held on the printed circuit board 14 while ensuring conduction stability and more stably positioning the connection portions 82 at symmetric positions across a gap.

Moreover, in the present embodiment, the first and second press-fit lead portions 78 and 80 have locking protrusion portions 88 on the tip side relative to the first and second press-fit portions 84 and 86. The locking protrusion portions 88 have an approximately triangular cross-sectional shape and protrude outward toward respective sides in the plate width direction of the connection portion 82, and when the first and second press-fit lead portions 78 and 80 undergo elastic deformation due to being inserted into the through-holes 44 and then undergo elastic restoration after passing through the through-holes 44, the locking protrusion portions 88 become locked to the lower surface 42 of the printed circuit board 14 (see FIG. 9). In this way, according to the present embodiment, due to the elastic restoration force of the first and second press-fit lead portions 78 and 80, that is to say the press-fitting force of the first and second press-fit lead portions 78 and 80, the locking protrusion portions 88 are stably held at a position of being locked and fixed to the lower surface 42 of the printed circuit board 14. Accordingly, even when removing force is applied to the circuit board terminal 76, the circuit board terminal 76 can be held stably on the printed circuit board 14, and it is possible to ensure more stable positioning and fixture of the circuit board terminal 76 on the printed circuit board 14.

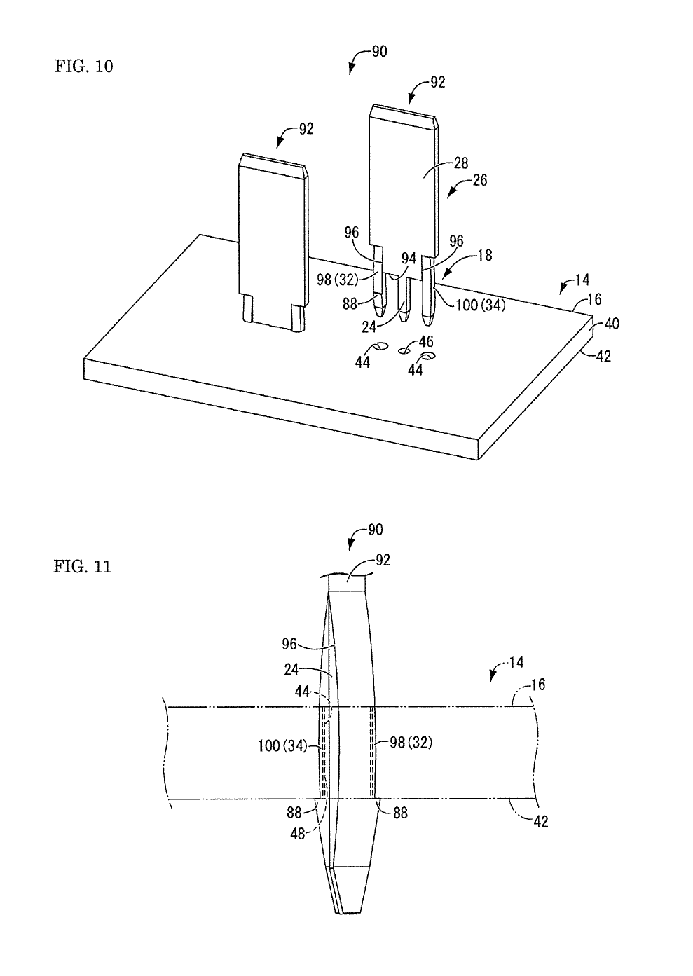

Furthermore, a terminal-equipped printed circuit board 90 according to a fourth embodiment of the present invention will be described in detail with reference to FIGS. 10 and 11. Members and portions having a structure similar to those in the above embodiments will be denoted in these figures by the same reference signs as in the above embodiments, thereby omitting detailed descriptions for them. This terminal-equipped printed circuit board 90 is different from the other aspect of the first embodiment in that a circuit board terminal 92 includes an abutting surface 94 that abuts against the upper surface 16 of the printed circuit board 14, and cut portions 96 are formed so as to extend upward from the abutting surface 94 in a direction away from the printed circuit board 14, such that the base portions of first and second press-fit lead portions 98 and 100 are located higher than the abutting surface 94 is.

According to the present embodiment, by providing the cut portions 96, the length (arm length) from the base portions of the first and second press-fit lead portions 98 and 100, which correspond to the fulcrum, to the first and second press-fit portions 32 and 34, which correspond to the point of effort, can be extended without changing the length of the circuit board terminal 92 itself, thus making it possible to reduce the amount of insertion force needed for insertion of the circuit board terminal 92 into the through-holes 44. In the present embodiment, the locking protrusion portions 88 are also provided, and it goes without saying that these locking protrusion portions 88 achieve the same effects as in the third embodiment.

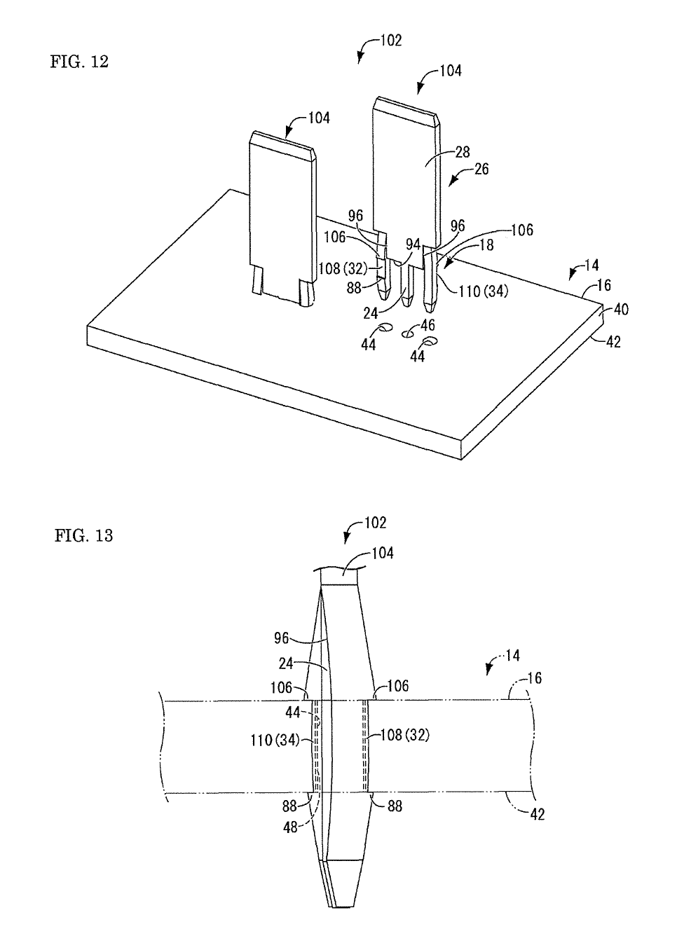

Additionally, a terminal-equipped printed circuit board 102 according to another aspect of the fourth embodiment will be described in detail with reference to FIGS. 12 and 13. Members and portions having a structure similar to those in the above embodiments will be denoted in these figures by the same reference signs as in the above embodiments, thereby omitting detailed descriptions for them. The present embodiment is different from the above embodiment in that first and second press-fit lead portions 108 and 110 of a circuit board terminal 104 have abutting protrusion portions 106 located on the base side relative to the first and second press-fit portions 32 and 34, and these abutting protrusion portions 106 become abutted against the upper surface 16 of the printed circuit board 14 during mounting to the printed circuit board 14. These abutting protrusion portions 106 have an approximately triangular cross-sectional shape and protrude in the same direction as the locking protrusion portions 88, and when the first and second press-fit lead portions 108 and 110 undergo elastic deformation due to being inserted into the through-holes 44 and then undergo elastic restoration after passing through the through-holes 44, the locking protrusion portions 88 become locked to the lower surface 42 of the printed circuit board 14, and the abutting protrusion portions 106 abut against the upper surface 16 of the printed circuit board 14.

According to the present embodiment, the abutting protrusion portions 106 become abutted against the upper surface 16 of the printed circuit board 14, and therefore even if excessive insertion force is applied to the circuit board terminal 104, the excessive insertion force can be distributed, thus making it possible for the circuit board terminal 104 to be able to be stably held in a self-standing state on the printed circuit board 14.

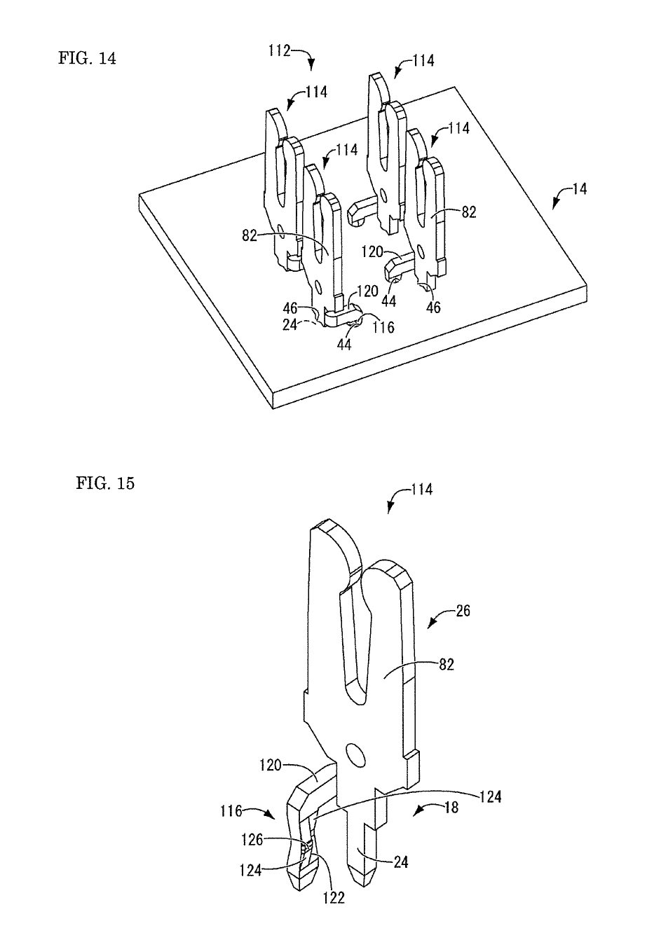

Lastly, a terminal-equipped printed circuit board 112 according to a fifth embodiment of the present invention will be described in detail with reference to FIGS. 14 to 16(b). Members and portions having a structure similar to those in the third embodiment will be denoted in these figures by the same reference signs as in the third embodiment, thereby omitting detailed descriptions for them. The present embodiment is different from the third embodiment in that a press-fit lead portion 116 and a press-in protrusion 24 of a circuit board terminal 114 are provided at different positions from each other in the plate thickness direction of a connection portion 82 (see FIG. 15). When the press-fit lead portion 116 and the press-in protrusion 24 having this configuration are respectively pressed into a through-hole 44 and a press-in hole 46 of the printed circuit board 14 (see FIG. 14), inclination and rotation of the circuit board terminal 114 on the printed circuit board 14 are advantageously suppressed, and it is possible to more stably maintain the upright state and conductivity of the circuit board terminal 114.

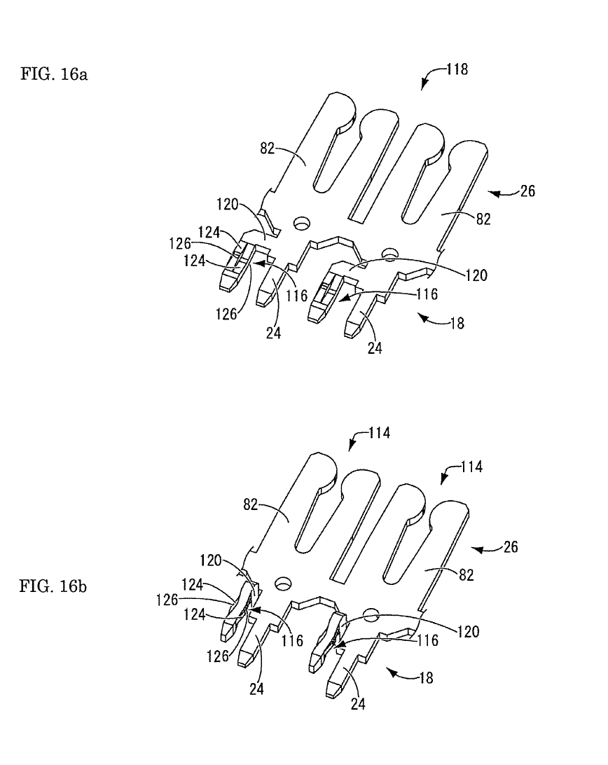

More specifically, as shown in FIGS. 16(a) and (b), the circuit board terminal 114 is formed in an integrated manner using a flat plate member 118 formed by performing press punching on a metal plate such as a copper plate whose surface has been plated with tin or the like. Specifically, with the flat plate member 118 shown in FIG. 16(a), the press-in protrusion 24 is located in a central portion with respect to the plate width direction of the connection portion 82, and the press-fit lead portion 116 is joined to the press-in protrusion 24 via a junction portion 120 that is shaped as a narrow flat plate and protrudes toward one side from the base portion of the press-in protrusion 24. By bending this junction portion 120 of the flat plate member 118 upward, it is possible to form a chain of circuit board terminals 114 in which the press-fit lead portion 116 is arranged at a position separated from the press-in protrusion 24 in the plate thickness direction of the connection portion 82 (the up-down direction in FIGS. 16(a) and (b)) as shown in FIG. 16(b). In this way, with use of the simple processing of press punching a metal flat plate and bending the junction portion 120, it is possible to form the circuit board terminal 114 in which the press-fit lead portion 116 and the press-in protrusion 24 are provided at a different positions from each other in the plate thickness direction of the connection portion 82. The press-in protrusion 24 is at the same position as the connection portion 82 in the plate thickness direction of the connection portion 82, and therefore similarly to the above embodiments, the press-in protrusion 24 can be held more stably against external force applied when an external terminal is connected to the connection portion 82. Moreover, in the present embodiment, as shown in FIG. 16(a), the press-fit lead portion 116 is provided in a rectangle defined by the pitch of a chain of connection portions 82 and the separation between the protruding end portions of the press-in protrusion 24 and the connection portion 82. Accordingly, the press-fit lead portion 116 can be provided without requiring an increase in the amount of the metal plate material for forming the circuit board terminal 114.

Note that in the press-fit lead portion 116, as shown in FIGS. 15 to 16, a slit 122 that extends in the length direction of the press-fit lead portion 116 is provided so as to penetrate the central portion of the press-fit lead portion 116. The central portions, with respect to the length direction, of the portions on the two sides of this slit 122 respectively protrude to one side and the other side in the thickness direction of the press-fit lead portion 116, thus forming a pair of elastic press-fit pieces 124, 124. A press-fit portion 126 is constituted by the outward surfaces of the pair of elastic press-fit pieces 124, 124. In this way, in the present embodiment, the two sides of the slit 122 provided in the central portion of the press-fit lead portion 116 protrude in mutually opposite directions so as to obtain a so-called action pin shape, thus constituting the press-fit lead portion 116. Accordingly, the press-fit lead portion 116 can be pressed into the through-hole 44 with a small amount of press-in force, and an advantageous area of press-fitting of the press-fit portions 126 against the through-hole 44 can be ensured. Moreover, even with the press-fit lead portion 116 having this action pin shape, the positions of the press-fit lead portion 116 and the press-in protrusion 24 are different from each other in the plate thickness direction of the connection portion 82, thus making it possible to advantageously prevent rolling of the circuit board terminal 114.

Although embodiments of the present invention have been described in detail above, the present invention is not limited by these specific descriptions. For example, although it is described in the above embodiments that the press-fit lead portions and the press-in protrusions 24 of the first and second press-fit lead portions 20 and 22 and the like have a rectangular cross-sectional shape, of course there is no limitation to this shape, and members having a circular, elliptical, or polygonal cross-sectional shape may be selected. In the case of the through-holes 44 and the press-in holes 46 as well, holes having a circular or elliptical cross-sectional shape, or having a polygonal cross-sectional shape can be selected. Additionally, printed wiring may be provided in an inner layer of the printed circuit board 14. Note that although the press-fit lead portions and the press-in protrusions 24 of the first and second press-fit lead portions 20 and 22 and the like are provided on a straight line in the above embodiments, of course there is no limitation to this. Also, although it is described that the plating layer 48 is not provided on the inner circumferential surface of the press-in holes 46, the plating layer 48 may be provided.

1. A terminal-equipped printed circuit board in which a circuit board terminal is provided upright on an upper surface of a printed circuit board,
wherein the printed circuit board includes a press-in hole and a through-hole that has a conduction portion,
the circuit board terminal includes a press-in protrusion and a press-fit lead portion that has a press-fit portion,
the circuit board terminal and the conduction portion are brought into conduction by the press-fit lead portion being inserted into the through-hole and the press-fit portion being press-fitted against the conduction portion of the through-hole, and
the circuit board terminal is positioned on and fixed to the printed circuit board by the press-in protrusion being pressed into the press-in hole.

2. The terminal-equipped printed circuit board according to claim 1, wherein the press-fit lead portion has a locking protrusion portion located on a tip side relative to the press-fit portion, the press-fit lead portion undergoes elastic deformation due to the locking protrusion portion being inserted into the through-hole, and, when the locking protrusion portion has passed through the through-hole, the press-fit lead portion undergoes elastic restoration and the locking protrusion portion becomes locked to a lower surface of the printed circuit board.

3. The terminal-equipped printed circuit board according to claim 1, wherein the press-fit lead portion has an abutting protrusion portion located on a base side relative to the press-fit portion, and in a state in which the circuit board terminal is mounted to the printed circuit board, the abutting protrusion portion abuts against the upper surface of the printed circuit board.

4. The terminal-equipped printed circuit board according to claim 1, wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

5. The terminal-equipped printed circuit board according to claim 4, wherein the circuit board terminal has a first press-fit lead portion and a second press-fit lead portion that are provided at positions with a gap therebetween in a plate width direction of the connection portion, the first press-fit lead portion has the first press-fit portion in an intermediate portion with respect to a length direction, and the second press-fit lead portion has the second press-fit portion in an intermediate portion with respect to the length direction.

6. The terminal-equipped printed circuit board according to claim 1,
wherein a tip side of the circuit board terminal, which protrudes above the upper surface of the printed circuit board and is connected to a base side on which the press-fit lead portion and the press-in protrusion are provided, is a flat plate-shaped connection portion, and the circuit board terminal has a first press-fit lead portion and a second press-fit lead portion that are provided at positions with a gap therebetween in a plate width direction of the connection portion, and
the first press-fit lead portion and the second press-fit lead portion are formed with a curved shape so as to protrude outward toward respective sides in the plate width direction of the connection portion, and protruding end surfaces of the press-fit lead portions are the press-fit portions.

7. The terminal-equipped printed circuit board according to claim 1, wherein the circuit board terminal has an abutting surface that abuts against the upper surface of the printed circuit board, and a cut portion is formed so as to extend upward from the abutting surface in a direction away from the printed circuit board such that a base portion of the press-fit lead portion is located higher than the abutting surface is.

8. The terminal-equipped printed circuit board according to claim 1, wherein a tip side of the circuit board terminal, which protrudes above the upper surface of the printed circuit board and is connected to a base side on which the press-fit lead portion and the press-in protrusion are provided, is a flat plate-shaped connection portion, and the press-fit lead portion and the press-in protrusion are provided at different positions from each other in a plate thickness direction of the connection portion.

9. The terminal-equipped printed circuit board according to claim 8, wherein the circuit board terminal that includes the press-fit lead portion, the press-in protrusion, and the connection portion is formed in an integrated manner by performing punching on a metal flat plate, the press-in protrusion is located in a central portion with respect to a plate width direction of the connection portion, and the press-fit lead portion, which is joined to the press-in protrusion via a junction portion that protrudes to one side from the press-in protrusion, is provided at a position that is separated from the press-fit lead portion in the plate thickness direction of the connection portion by bending the junction portion.

10. The terminal-equipped printed circuit board according to claim 8, wherein a slit that extends in a length direction of the press-fit lead portion is provided so as to penetrate a central portion of the press-fit lead portion, central portions, with respect to the length direction, of portions of the press-fit lead portion on respective sides of the slit respectively protrude toward one side and another side in a thickness direction of the press-fit lead portion and thus constitute a pair of elastic press-fit pieces, and the press-fit portion is constituted by outward surfaces of the pair of elastic press-fit pieces.

11. The terminal-equipped printed circuit board according to claim 2, wherein the press-fit lead portion has an abutting protrusion portion located on a base side relative to the press-fit portion, and in a state in which the circuit board terminal is mounted to the printed circuit board, the abutting protrusion portion abuts against the upper surface of the printed circuit board.

12. The terminal-equipped printed circuit board according to claim 2, wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

13. The terminal-equipped printed circuit board according to claim 3, wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

14. The terminal-equipped printed circuit board according to claim 2, wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

15. The terminal-equipped printed circuit board according to claim 3, wherein a tip side of the circuit board terminal, which protrudes above the upper surface of the printed circuit board and is connected to a base side on which the press-fit lead portion and the press-in protrusion are provided, is a flat plate-shaped connection portion, a first press-fit portion of the circuit board terminal protrudes in a circular arc shape toward one side in a plate thickness direction of the connection portion, and a second press-fit portion of the circuit board terminal protrudes in a circular arc shape toward another side in the plate thickness direction of the connection portion.

16. The terminal-equipped printed circuit board according to claim 2, wherein a tip side of the circuit board terminal, which protrudes above the upper surface of the printed circuit board and is connected to a base side on which the press-fit lead portion and the press-in protrusion are provided, is a flat plate-shaped connection portion, and the circuit board terminal has a first press-fit lead portion and a second press-fit lead portion that are provided at positions with a gap therebetween in a plate width direction of the connection portion, and
the first press-fit lead portion and the second press-fit lead portion are formed with a curved shape so as to protrude outward toward respective sides in the plate width direction of the connection portion, and protruding end surfaces of the press-fit lead portions are the press-fit portions.

17. The terminal-equipped printed circuit board according to claim 9, wherein a slit that extends in a length direction of the press-fit lead portion is provided so as to penetrate a central portion of the press-fit lead portion, central portions, with respect to the length direction, of portions of the press-fit lead portion on respective sides of the slit respectively protrude toward one side and another side in a thickness direction of the press-fit lead portion and thus constitute a pair of elastic press-fit pieces, and the press-fit portion is constituted by outward surfaces of the pair of elastic press-fit pieces.
